(19) United States
(12) Patent Application Publication
(10) Pub. No.: US 2014/0252556 A1
(43) Pub. Date: Sep. 11, 2014

(54) SINGLE-MASK SPACER TECHNIQUE FOR SEMICONDUCTOR DEVICE FEATURES

(71) Applicant: INTERNATIONAL BUSINESS MACHINES CORPORATION, Armonk, NY (US)

(72) Inventors: Chung H. Lam, Peekskill, NY (US); Jing Li, Ossining, NY (US)

(73) Assignee: International Business Machines Corporation, Armonk, NY (US)

(21) Appl. No.: 13/786,520

(22) Filed: Mar. 6, 2013

(51) Int. Cl. H01L 21/768; H01L 23/48

(52) U.S. Cl. CPC H01L 21/768; H01L 23/481
USPC 257/618; 438/667

(57) ABSTRACT

A method for fabricating semiconductor features. The method includes forming a first layer over a substrate. Forming a plurality of first holes in the first layer. The first layer includes sidewalls separating at least a portion of each first hole. The first holes include overlapping holes that are not separated by the sidewalls. Forming a plurality of spacers on the substrate and first layer. The spacers include spacer sidewalls separating adjacent overlapping holes. Etching exposed portions of the substrate to form a plurality of second holes.

### BACKGROUND

This invention relates to the fabrication of semiconductor devices. More particularly, the present invention relates to a method for fabricating sub-lithographic semiconductor device features.

In general, semiconductor device scaling may be restricted by the current resolution limits of lithography technology. With the ongoing down-scaling of semiconductor devices and drive to increase feature density, methods such as Double Patterning Technology have been introduced as solutions to the resolution limits of current lithography equipment. Double Patterning Technology has allowed fabrication of device features beyond the lithographic printing limit utilizing a plurality of masking, etch, and/or spacing techniques.

However, the formation of semiconductor device arrays with sub-lithographic features, such as contacts and memory elements, is highly sensitive to variations in precision and uniformity. These issues are exacerbated as the down-scaling of semiconductor devices require decreasing space between adjacent features. For example, optical proximity effects may result in shorted devices when features such as contacts overlap. Conventional methods such as Double Patterning may not resolve such issues that may arise. Thus the efficiency of conventional methods for such sensitive features is reduced.

### BRIEF SUMMARY

An aspect of the invention is a method for fabricating semiconductor features. The method includes forming a first layer over a substrate. The method also includes forming a plurality of first holes in the first layer. The first layer includes sidewalls separating the first holes. The first holes include overlapping holes that are not separated by the sidewalls. The method includes forming a plurality of spacers on the substrate. The spacers include spacer sidewalls separating adjacent overlapping holes. The method also includes etching exposed portions of the substrate to form a plurality of second holes.

Another aspect of the invention is a semiconductor device array structure. The structure includes a first layer formed over a substrate. The first layer includes a plurality of first holes such that a portion of at least two of the first holes are overlapping. The structure also includes a plurality of spacers formed in the first holes, such that the spacers include spacer sidewalls circumscribing a plurality of spacer holes.

### BRIEF DESCRIPTION OF DRAWINGS

FIG. 1 is a diagram of a memory array structure after a lithographic process, in accordance to one embodiment of the present invention.

FIG. 2A is a diagram of an intermediary step depicting a first layer deposited on a substrate, in accordance to one embodiment of the present invention.

FIG. 2B is a diagram of an intermediary step depicting a photoresist pattern formed on top of a first layer, in accordance to one embodiment of the present invention.

FIG. 2C is a diagram of an intermediary step depicting first holes etched into a first layer, in accordance to one embodiment of the present invention.

FIG. 2D is a diagram of an intermediary step depicting a spacer layer conformally deposited over a first layer and substrate, in accordance to one embodiment of the present invention.

FIG. 2E is a diagram of an intermediary step depicting spacers formed on a substrate, in accordance to one embodiment of the present invention.

FIG. 2F is a diagram of an intermediary step depicting second holes formed into a substrate, in accordance to one embodiment of the present invention.

FIG. 3A is a diagram of an intermediary step depicting a first layer deposited on a substrate, in accordance to one embodiment of the present invention.

FIG. 3B is a diagram of an intermediary step depicting a photoresist pattern formed on top of a first layer, in accordance to one embodiment of the present invention.

FIG. 3C is a diagram of an intermediary step depicting first holes etched into a first layer, in accordance to one embodiment of the present invention.

FIG. 3D is a diagram of an intermediary step depicting a spacer layer conformally deposited over a first layer and substrate, in accordance to one embodiment of the present invention.

FIG. 3E is a diagram of an intermediary step depicting spacers formed on a substrate, in accordance to one embodiment of the present invention.

FIG. 3F is a diagram of an intermediary step depicting second holes formed into a substrate, in accordance to one embodiment of the present invention.

FIG. 4A is a diagram of an intermediary step depicting overlapping holes in a first layer, in accordance to one embodiment of the present invention.

FIG. 4B is a diagram of an intermediary step depicting spacers separating overlapping holes, in accordance to one embodiment of the present invention.

FIG. 4C is a diagram of an intermediary step depicting second holes etched into a substrate, in accordance to one embodiment of the present invention.

FIG. 5A is a diagram of a semiconductor array structure depicting staggered spacer holes, in accordance to one embodiment of the present invention.

FIG. 5B is a diagram of a semiconductor array structure including spacer sidewalls circumscribing spacer holes, in accordance to one embodiment of the present invention.

FIG. 6 is a flowchart illustrating an example method of forming contacts in sub-lithographic holes, in accordance to one embodiment of the present invention.

### DETAILED DESCRIPTION

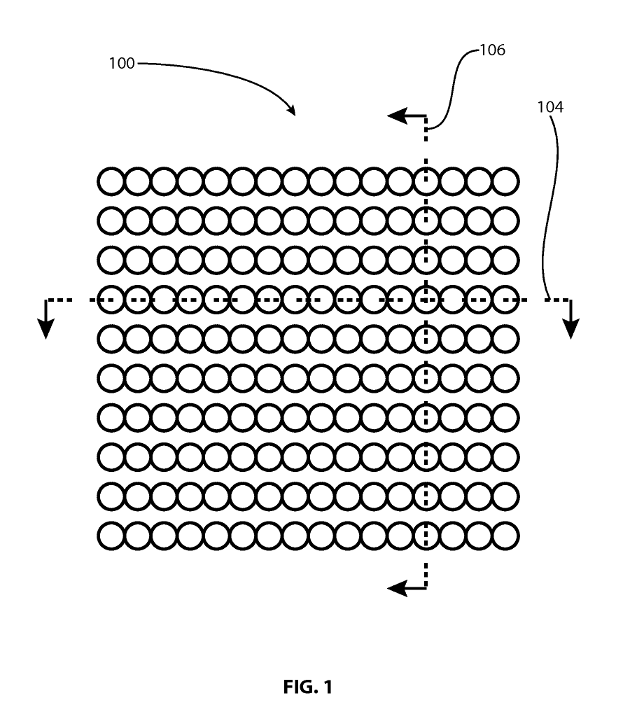

The present invention is described with reference to various embodiments of the invention. Throughout the description of the invention, reference is made to FIG. 1 through 6.

Additionally, relative terms, such as “top”, “over”, and “down” are employed with respects to other elements in the described embodiments and figures. Such terms are meant only to describe the referenced embodiments. Therefore, the present invention encompasses alternative orientations of the suggested embodiments.

Embodiments of the present invention provide possible methods of fabricating semiconductor device features. An aspect of the present invention provides a method of utilizing a plurality of spacers to define sub-lithographic holes in which a semiconductor device feature is formed, such that the holes minimally spaced without shorting.

FIG. 1 schematically depicts a top-down view of a memory array structure 100 after a lithographic process, in accordance to one embodiment of the present invention. The diagram includes cross-section A 104 and cross-section B 106.

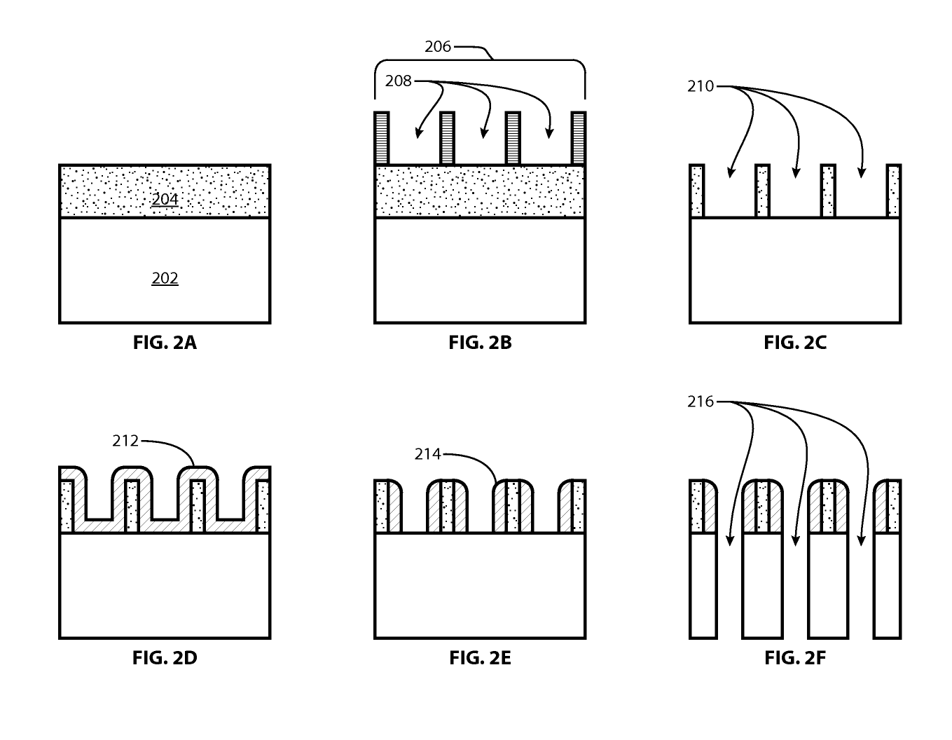

The diagrams from FIG. 2A through 2F are views from cross-section A 104 of intermediary steps during fabrication of a memory array structure, in accordance to one embodiment of the present invention.

FIG. 2A schematically depicts a first layer 204 on top of a substrate 202. In this embodiment, the substrate 202 is comprised of a silicon-oxide (SiO) material. FIG. 2B schematically depicts a photoresist pattern 206 formed over the first layer 204. The photoresist pattern 206 includes an array of mask holes 208. In this embodiment, with regards to the axis along cross-section A 104, the mask holes 208 have a width equal to the minimal photolithographic limit and the mask holes 208 are spaced at the minimal photolithographic limit. FIG. 2C schematically depicts first holes 210 etched into the first layer 204. The first layer 204 includes first layer sidewalls 211. In this diagram, the photoresist pattern 206 has been removed.

FIG. 2D schematically depicts a spacer layer 212 conformally deposited over the first layer 204 and substrate 202. In this embodiment, the spacer layer 212 is comprised of a silicon-nitride (SiN) material. FIG. 2E schematically depicts spacers 214 on the substrate 202, after etching portions of the spacer layer 212. FIG. 2F schematically depicts second holes 216 etched into the substrate 202. In this embodiment, the second holes 216 penetrate through the substrate 202.

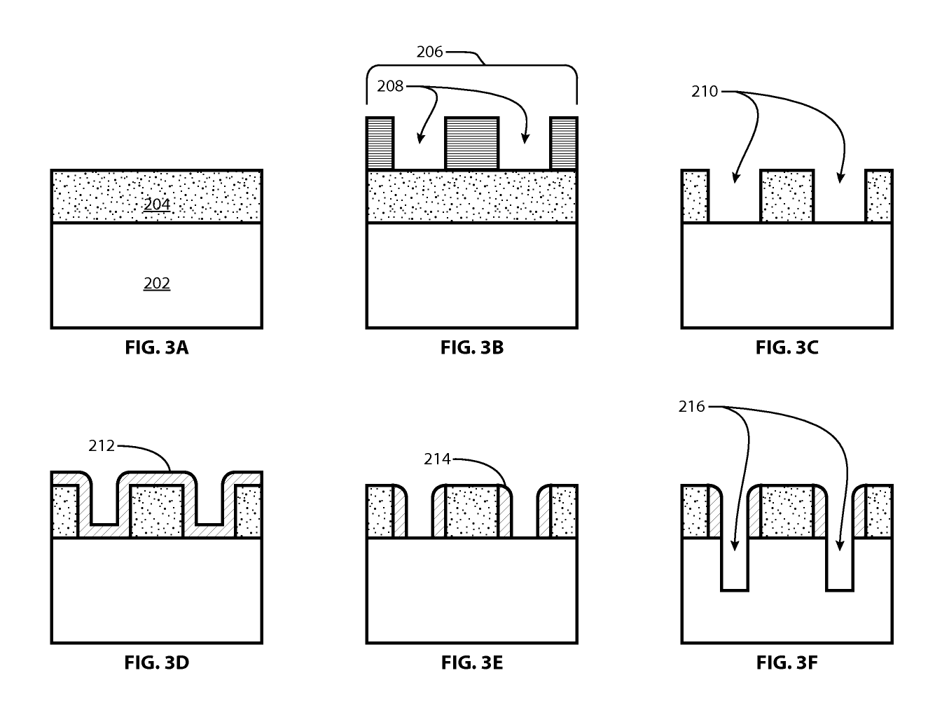

The diagrams from FIG. 3A through 3F are views from cross-section B 106 of intermediary steps during fabrication of a memory array structure, in accordance to one embodiment of the present invention.

FIG. 3A schematically depicts a first layer 204 on top of a substrate 202. In this embodiment, the substrate 202 is comprised of a silicon-oxide (SiO) material. FIG. 3B schematically depicts a photoresist pattern 206 formed over the first layer 204. The photoresist pattern 206 includes an array of mask holes 208. In this embodiment, with regards to the axis along cross-section B 106, the mask holes 208 have a width equal to the minimal photolithographic limit and the mask holes 208 are spaced substantially greater than the minimal photolithographic limit. FIG. 3C schematically depicts first holes 210 etched into the first layer 204. In this diagram, the photoresist pattern 206 has been removed.

FIG. 3D schematically depicts a spacer layer 212 conformally deposited over the first layer 204 and substrate 202. In this embodiment, the spacer layer 212 is comprised of a silicon-nitride (SiN) material. FIG. 3E schematically depicts spacers 214 on the substrate 202, after etching portions of the spacer layer 212. FIG. 3F schematically depicts second holes 216 etched into the substrate 202.

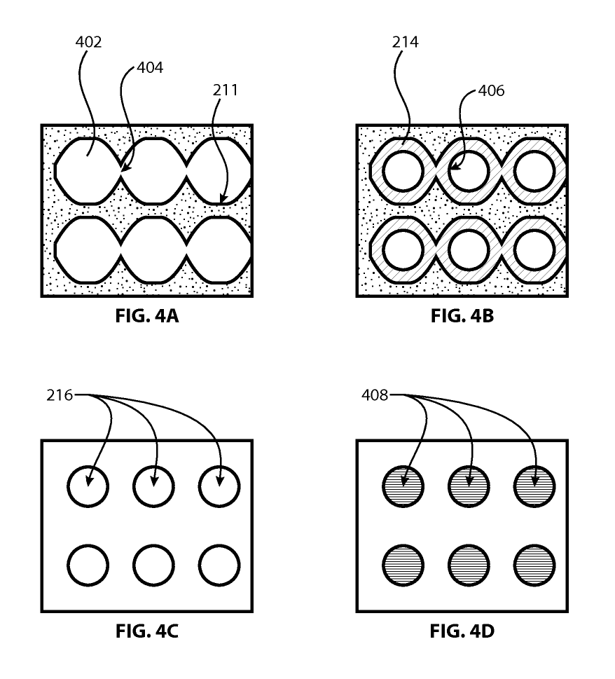

The diagrams from FIG. 4A through 3C are top-down views of intermediary steps during fabrication of a memory array structure, in accordance to one embodiment of the present invention. FIG. 4A schematically depicts overlapping holes 402 etched into the first layer 204. The overlapping holes 402 include portions not separated by the first layer sidewalls 211. FIG. 4B schematically depicts spacers 214 formed within the overlapping holes 402. The spacers 214 include spacer sidewalls 406 separating the overlapping holes 402. FIG. 4C schematically depicts second holes 208 etched into the substrate 202. In this diagram, the spacers 214 and first layer 204 have been removed. FIG. 4D schematically depicts a plurality of contacts 408 formed in the second holes 216. One skilled in the art would recognize that the contacts 408 may be comprised of a variety of conductive materials.

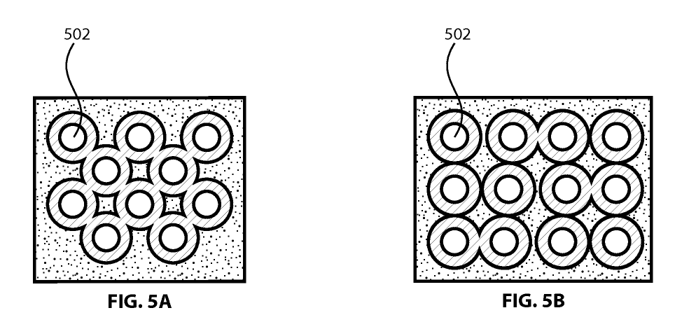

FIG. 5A and FIG. 5B are top-down views of a semiconductor device array structures, in accordance to the present invention. FIG. 5A schematically depicts spacer sidewalls 406 circumscribing a plurality of spacer holes 502. In this embodiment, all the first holes 210 are overlapping holes 402. The first holes 210 are staggered in alignment along one axis. FIG. 5B schematically depicts spacer sidewalls 406 circumscribing a plurality of spacer holes 502. In this embodiment, there are

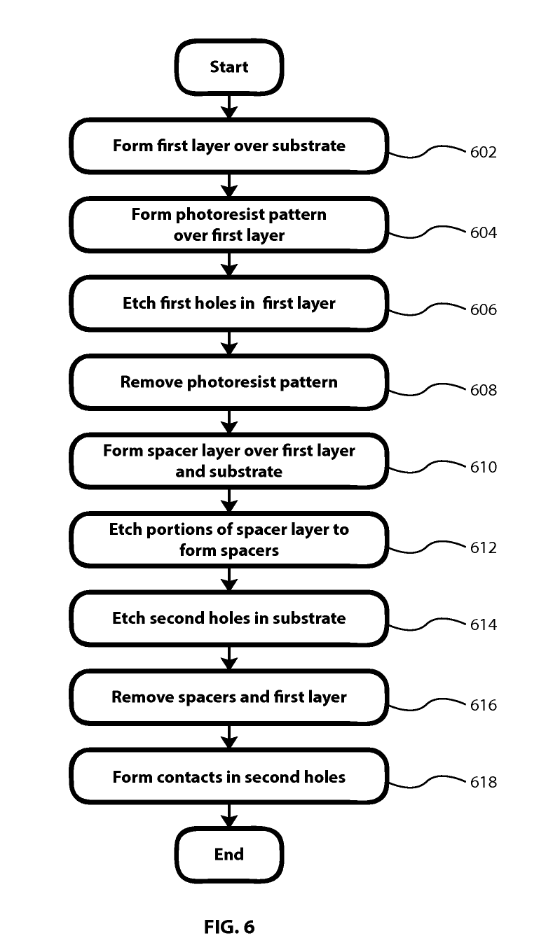

FIG. 6 is a flowchart illustrating an example method of forming contacts in sub-lithographic holes, in accordance to one embodiment of the present invention. FIG. 6 will be described with references to FIG. 2A through FIG. 4C. The method begins with forming step 602. At forming step 602, a first layer 204 is deposited over the substrate 202 (FIGS. 2A and 3A). After forming step 602, the method continues to forming step 604.

At forming step 604, a photoresist pattern 206 is formed over the first layer 204, such that portions of the first layer 204 are exposed (FIGS. 2B and 3B). In some embodiments, forming step 604 includes applying optical proximity correction (OPC) techniques to enhance the fidelity of patterning. After forming step 604, the method continues to etching step 606. At etching step 606, the exposed portions of the first layer 204 are etched to form a plurality of first holes 210. After etching step 606, the method continues to removing step 608. At removing step 608, the photoresist pattern 206 is removed (FIGS. 2C, 3C and 4A). After removing step 608, the method continues to forming step 610.

At forming step 610, a spacer layer 212 is conformally deposited on the first layer 204 and substrate 202 (FIG. 2D and 3D). One skilled in the art would recognize that a variety of processes can be utilized, such as atomic layer deposition (ALD) or chemical vapor deposition (CVD). After forming step 610, the method continues to etching step 612. At etching step 612, portions of the spacer layer 212 are etched to form a plurality of spacers 214 (FIGS. 2E, 3E, 4B, 5A and 5B). One skilled in the art would recognize that a variety of processes can be utilized, such as a reactive ion etch process (RIE). After etching step 612, the method continues to etching step 614.

At etching step 614, a plurality of second holes 216 are etched into the substrate 202 (FIGS. 2F, 3F and 4C). One skilled in the art would recognize that a variety of processes can be utilized, such as a reactive ion etch process (RIE). After etching step 614, the method continues to removing step 616. At removing step 616, the spacers 214 and first layer 204 are removed. One skilled in the art would recognize that a variety of selective etches can be utilized to remove the spacers 214 and first layer 204. After removing step 616, the method continues to forming step 618. At forming step 618, a plurality of contacts 408 are formed in the second holes 216 (FIG. 4D). After forming step 618, the method is complete.

Having described preferred embodiments for a method of fabricating semiconductor device features, it is noted that modifications and variations can be made by persons skilled in the art in light of the above teachings. It is therefore to be understood that changes may be made in the particular embodiments disclosed which are within the scope and spirit of the invention as outlined by the appended claims. Having thus described aspects of the invention, with the details and particularity required by the patent laws, what is claimed and desired protected by Letters Patent is set forth in the appended claims.

1. A method for fabricating a semiconductor device, comprising:
forming a first layer over a substrate;
forming a plurality of rounded first holes in the first layer using a lithographic process such that the first layer includes first layer sidewalls separating at least a portion of each first hole, and wherein the first holes include pairs of only two overlapping holes, the overlapping holes including pointed portions not separated by the first layer sidewalls;
forming a plurality of spacers on the substrate, such that the spacers include spacer sidewalls separating adjacent overlapping holes; and
etching exposed portions of the substrate, forming a plurality of second holes, each of the second holes having a single opening and is not connected to any other of the second holes.

2. The method of claim 1, wherein the lithographic process comprises:
forming a photoresist pattern over the first layer, such that the photoresist pattern includes mask holes exposing portions of the first layer;
etching exposed portions of the first layer; and
removing the photoresist pattern.

3. The method of claim 2, wherein the lithographic process further comprises optical proximity correction (OPC) techniques.

4. The method of claim 1, wherein forming the spacers comprises:
forming a spacer layer over the first layer and substrate, such that the spacer layer includes spacer sidewalls that separate the portions of the first holes not separated by first layer sidewalls; and
etching portions of the spacer layer, resulting in the spacers.

5. The method of claim 4, wherein the spacer layer is formed with a conformal deposition process, such as atomic layer deposition (ALD) or chemical vapor deposition (CVD).

6. The method of claim 4, wherein etching portions of the spacer layer comprises a reactive ion etch.

7. The method of claim 1, wherein the second holes penetrate through the substrate.

8. The method of claim 1, further comprising removing the spacers and first layer.

9. The method of claim 1, further comprising forming a plurality of contacts within the second holes.

10. The method of claim 1, further comprising forming a plurality of semiconductor device elements within the second holes.

11. The method of claim 1, wherein the substrate is comprised of a silicon-oxide (SiO) material.

12. The method of claim 1, wherein the first layer is comprised of a silicon-nitride (SiN) material.

13. The method of claim 1, wherein the spacer is comprised of a silicon (Si) material.

14. The method of claim 1, wherein the spacer width is utilized to minimize the dimensions of the second holes.

15. The method of claim 1, wherein the second holes are arranged in six-feature squares, such that a first axis contains three features per square and a second axis contains two features per square.

16. The method of claim 1, wherein the second holes are arranged in four-feature squares, such that a first axis and second axis both contain two features per square.

17. The method of claim 1, wherein the first holes are staggered in alignment, such that the space between the first holes is minimized.

18-21. (canceled)
